(19) United States
(12) Patent Application Publication
(10) Pub. No.: US 2012/0252143 A1
(43) Pub. Date: Oct. 4, 2012

(54) METHOD OF MANUFACTURING ORGANIC LIGHT EMITTING DEVICE

(75) Inventors: Manabu Otsuka, Narashino-shi (JP); Toshihide Kimura, Ebina-shi (JP); Tomoyuki Hiroki, Mobara-shi (JP); Taro Endo, Kawasaki-shi (JP); Itaru Takaya, Chiba-shi (JP); Koichi Ishige, Mobara-shi (JP); Nobuhiko Sato, Mobara-shi (JP)

(73) Assignee: CANON KABUSHIKI KAISHA, Tokyo (JP)

(21) Appl. No.: 13/426,076

(22) Filed: Mar. 21, 2012

(30) Foreign Application Priority Data
Mar. 30, 2011 (JP) 2011-074837
Sep. 2, 2011 (JP) 2011-191414

(51) Int. Cl. H01L 51/40

(52) U.S. Cl. 438/22; 257/E51.018

(57) ABSTRACT

To solve a problem that, in a method of manufacturing an organic light emitting device using a step of releasing a layer formed on a release layer by dissolving the release layer, released film flakes are not dissolved in a removing liquid for dissolving the release layer, and thus may drift in the removing liquid and may adhere to a surface of a substrate after patterning to cause defective patterning, provided is a method of manufacturing an organic light emitting device, including forming the release layer continuously over multiple light emitting portions to cause the size of the released film flakes to be large. This may reduce the possibility that the released film flakes adhere to the surface of the substrate and may facilitate, even when the released film flakes once adhere to the surface of the substrate, removal of the released film flakes later, thereby suppressing defective patterning.

### BACKGROUND OF THE INVENTION

1. Field of the Invention

The present invention relates to a method of manufacturing an organic light emitting device including a step of patterning an organic compound layer using photolithography. In particular, the present invention relates to a manufacturing method including a step of patterning an organic compound layer with use of a release layer which is formed in a predetermined pattern by photolithography.

2. Description of the Related Art

Japanese Patent No. 4578026 discloses a method of manufacturing an electroluminescence element in which an organic emission layer is patterned using photolithography. A specific manufacturing method is as follows. First, a first emission layer which is insoluble in a photoresist material is formed on a substrate. A photoresist layer is formed on the first emission layer, and the photoresist layer is patterned so that the photoresist layer is left in a portion in which a first light emitting portion is to be formed. After the first emission layer in a region in which the photoresist layer is not left is removed, a second emission layer is formed on the substrate having the first emission layer and the photoresist layer left on a surface thereof. After that, a removing liquid is brought into contact with the remaining photoresist layer to release the photoresist layer together with the second emission layer formed thereon, thereby forming the first light emitting portion and a second light emitting portion.

Further, Japanese Patent No. 4544811 discloses a method of manufacturing an electroluminescence element which is similar to the manufacturing method disclosed in Japanese Patent No. 4578026 and which may, by providing between an organic compound layer and a resist layer a release layer which is excellent in releasability, release with ease an unnecessary layer such as a photoresist layer which is difficult to release from the organic compound layer.

As in Japanese Patent Nos. 4578026 and 4544811, in a step of releasing together with a patterned photoresist layer or release layer a layer formed on the patterned photoresist layer or release layer, these layers are brought into contact with a solvent (removing liquid) which dissolves these layers, thereby dissolving the layers. As the removing liquid, a liquid which selectively dissolves the photoresist layer or the release layer is used. Film flakes released when the photoresist layer or the release layer is dissolved are not dissolved in the removing liquid, and thus, drift in the removing liquid, and may adhere to the surface of the substrate after the patterning to cause defective patterning.

Japanese Patent Nos. 4578026 and 4544811 do not describe a specific pattern of the organic compound layer, but, when the size of the film flakes released in patterning is small and the number of the film flakes is large, the possibility that the released film flakes adhere to the surface of the substrate to cause defective patterning becomes stronger.

### SUMMARY OF THE INVENTION

It is an object of the present invention to reduce, through increase of the size of a formation pattern of a release layer, that is, the size of released film flakes, the possibility that the released film flakes adhere to the surface of a substrate and to facilitate, even when the released film flakes once adhere to the surface of the substrate, removal of the released film flakes later, thereby suppressing defective patterning.

In order to achieve the above-mentioned object, a method of manufacturing an organic light emitting device according to the present invention includes: forming a first organic compound layer on a substrate having multiple first electrodes formed thereon corresponding to multiple light emitting portions, the first organic compound layer at least including a first emission layer; forming on the first organic compound layer a release layer continuously over a part of the multiple light emitting portions; removing a part of the first organic compound layer on which the release layer is not formed; forming a second organic compound layer on a part of the substrate from which the first organic compound layer is removed and on the release layer, the second organic compound layer at least including a second emission layer; and bringing the substrate having the second organic compound layer formed thereon into contact with a removing liquid for selectively dissolving the release layer and removing the release layer and the second organic compound layer formed on the release layer.

According to the present invention, the release layer is formed continuously over the multiple light emitting portions, and thus the size of film flakes of the second organic compound layer and the like, which are released by bringing the release layer into contact with the removing liquid, may be caused to be large. Therefore, compared with a case where the organic compound layers are separately patterned with respect to the respective first electrodes (respective light emitting portions), the number of the released film flakes is reduced, and thus, adhesion of the released film flakes to the substrate may be suppressed. As a result, leakage, a short circuit, light emission failure, and the like which are caused by adhesion of the released film flakes to the substrate after the patterning may be suppressed and an organic light emitting device having satisfactory performance may be obtained.

Further features of the present invention will become apparent from the following description of exemplary embodiments with reference to the attached drawings.

### BRIEF DESCRIPTION OF THE DRAWINGS

FIGS. 1A and 1B are schematic views illustrating an organic light emitting device manufactured by a manufacturing method according to the present invention.

FIGS. 2A, 2B, 2C, 2D, 2E, 2F, 2G, 2H, 2I, 2J, 2K, 2L, 2M, and 2N illustrate an example of the manufacturing method according to the present invention.

FIGS. 3A, 3B, 3C, 3D, 3E, 3F, 3G, 3H, 3I, 3J, 3K, 3L, 3M, 3N, 3O, and 3P illustrate another example of the manufacturing method according to the present invention.

FIGS. 4A, 4B, and 4C illustrate a formation pattern of organic compound layers of the manufacturing method according to the present invention.

FIGS. 5A, 5B, and 5C illustrate another formation pattern of organic compound layers of the manufacturing method according to the present invention.

FIGS. 6A and 6B illustrate still another formation pattern of organic compound layers of the manufacturing method according to the present invention.

FIGS. 7A and 7B illustrate a comparison pattern of the formation pattern of the organic compound layers according to the present invention.

### DESCRIPTION OF THE EMBODIMENT

A method of manufacturing an organic light emitting device according to the present invention is described with reference to the attached drawings. Note that, a well-known or publicly known technology in the art may be applied to portions which are not specifically illustrated or described. Further, an embodiment described in the following is only an exemplary method of manufacturing a light emitting device according to the present invention, and the present invention is not limited thereto.

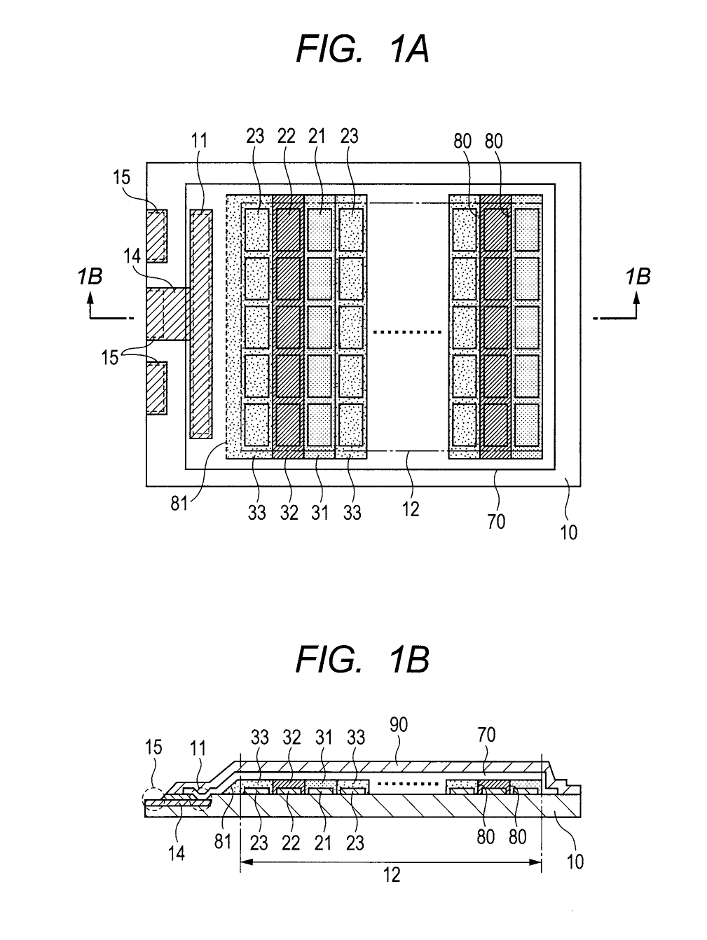

FIG. 1A is a schematic plan view of an organic light emitting device formed by a method of manufacturing an organic light emitting device according to the present invention, and FIG. 1B is a schematic sectional view taken along the line 1B-1B of FIG. 1A. First, the structure of the organic light emitting device is described.

A substrate 10 includes a light emitting region in which multiple light emitting portions are formed. An external connection terminal 15 for being supplied with power or a signal from the external is provided outside the light emitting region 12. In FIGS. 1A and 1B, only a state in which a part of the external connection terminal 15 is connected to a second electrode is illustrated, but another part of the external connection terminal 15 is electrically connected to a circuit layer (not shown) provided on the substrate 10.

Multiple first electrodes 21 to 23 are formed in the light emitting region 12 in a row direction and in a column direction with respect to the respective light emitting portions. Each of the first electrodes is electrically connected to the circuit layer (not shown). A first organic compound layer 31 at least including a first emission layer is provided on the first electrode 21, a second organic compound layer 32 at least including a second emission layer is provided on the first electrode 22, and a third organic compound layer 33 at least including a third emission layer is provided on the first electrode 23. The first emission layer, the second emission layer, and the third emission layer are layers which emit light of colors that are different from one another. Through assignment of a red (R) emission layer, a green (G) emission layer, and a blue (B) emission layer to the respective emission layers, a full-color image may be displayed. A second electrode 70 which is continuous over multiple light emitting portions is formed on the first to third emission layers. A laminate provided in each light emitting portion and including the first electrode, the second electrode, and the organic compound layer sandwiched between the first electrode and the second electrode is hereinafter referred to as a light emitting element. The light emitting element may be caused to emit light according to a signal which is input via the external connection terminal 15 to the circuit layer. Note that, the first electrode may also be provided so as to be common to the multiple light emitting portions. In other words, multiple light emitting portions may be provided for one first electrode. The second electrode is connected via a contact portion 11 and a wiring layer 14 to the external connection terminal 15.

A light emitting element using an organic compound layer is significantly deteriorated by moisture, and thus an encapsulation layer 90 for covering the light emitting element to suppress entrance of moisture into the light emitting region 12 from the external is provided. An organic material of the organic compound layer and the like is liable to allow moisture to pass therethrough, and thus, in order to suppress entrance of moisture into the light emitting region via the organic compound layer from the external, it is preferred that a part of the organic compound layer which surrounds the light emitting region 12 be removed to cut off a path through which moisture enters. The encapsulation layer 90 is made of a material which is highly resistant to moisture. Instead of the encapsulation layer 90 illustrated in FIGS. 1A and 1B, a glass cap or the like may be fixed to the substrate 10 with an adhesive which is less liable to allow moisture to pass therethrough to suppress entrance of moisture from the external.

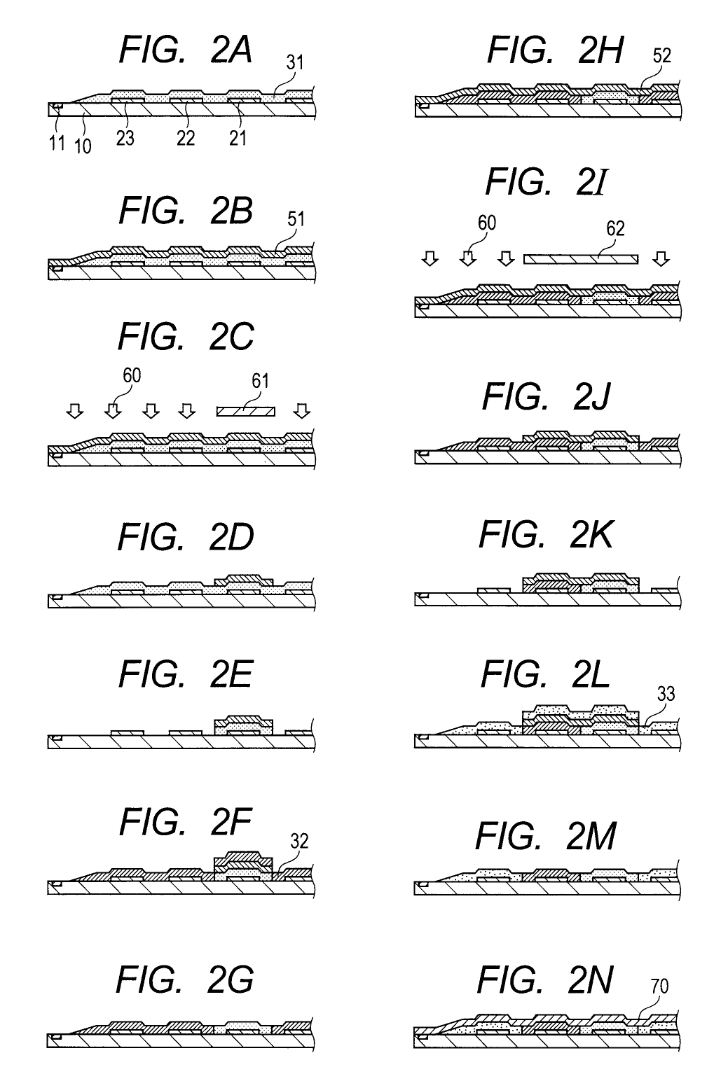

A method of manufacturing an organic light emitting device according to the present invention is described in detail in the following with reference to FIGS. 2A to 2N.

First, the substrate 10 having the multiple first electrodes 21 to 23 formed thereon according to the light emitting portions is prepared. As the substrate 10, an insulating substrate made of glass, a synthetic resin, or the like, a conductive substrate covered with an insulating film such as a silicon oxide film, a silicon nitride film, or a silicon oxynitride film, a semiconductor substrate, or the like may be used. However, in the case of a bottom emission type light emitting device, a transparent substrate is used. As necessary, the substrate 10 is provided with a drive circuit including a publicly known transistor (Tr), a planarized passivation layer, a pixel separation film, and the like.

The first electrode is an anode or a cathode. When the first electrode is used as an anode, a material having a high work function is used so as to facilitate injection of holes. Further, in the case of a top emission type organic light emitting device, from the viewpoint of enhancing the light extraction efficiency, it is preferred that a light reflective layer such as a metal layer of Al, Ag, Au, Pt, Cr, or the like, a film of an alloy thereof, a film of a laminate thereof, or the like be used as the first electrode. Further, a laminate film in which a transparent conductive layer of indium tin oxide, indium zinc oxide, or the like is formed on such a light reflective layer is also preferred.

The first electrode is formed by, first, forming a conductive layer on the entire surface of the substrate 10 using vacuum film formation such as sputtering or vapor deposition, and then, patterning the conductive layer with respect to each light emitting portion by publicly known photolithography. After the first electrode is formed, as necessary, a partition layer for defining the light emitting portions may be formed between the first electrodes to define a light emitting area of each light emitting portion. The partition layer may be formed using an insulating material such as a photosensitive polyimide.

The organic compound layers are formed on the entire surface of the substrate having the first electrodes formed thereon. Each of the organic compound layers at least includes the emission layer, and may include, as necessary, a functional layer such as a hole injection layer, a hole transport layer, a hole blocking layer, an electron blocking layer, an electron transport layer, or an electron injection layer.

The organic light emitting device according to the present invention is a light emitting device which includes multiple light emitting portions for emitting light of colors that are different from one another, and which may display an image in multiple colors. Therefore, in each light emitting portion, an organic compound layer including a different emission layer according to the color of emitted light is required to be selectively formed. However, there are cases in which functional layers other than the emission layer may be common to light emitting portions which emit different colors of light. In such cases, a layer to be formed after the emission layers are patterned may be formed as a common layer across the multiple light emitting portions which emit different colors of light.

As the emission layer, a publicly known low molecular material such as a triarylamine derivative, a stilbene derivative, polyarylene, an aromatic condensed polycyclic compound, an aromatic heterocyclic compound, an aromatic condensed heterocyclic compound, a metal complex compound, or a single oligomer or complex oligomer thereof may be used. Further, a publicly known high molecular material such as a polyparaphenylene vinylene derivative, a polythiophene derivative, a polyparaphenylene derivative, a polysilane derivative, a polyacethylene derivative, a polyfluorene derivative, a polyvinyl carbazole derivative, or a material formed by polymerizing the above-mentioned low molecular material may also be used. A low molecular material may be formed by vacuum deposition, and a high molecular material may be formed by an applying method such as spin coating or an ink jet method.

Layers which are formed are hereinafter referred to as a first organic compound layer, a second organic compound layer, and a third organic compound layer in the order of formation, and organic layers included therein are hereinafter referred to as a first emission layer, a second emission layer, and a third emission layer, respectively. The respective organic compound layers may be formed in a similar way.

Next, the first organic compound layer 31 which is first formed on the first electrodes is patterned using photolithography. A positive photoresist material is applied to the entire substrate having the first organic compound layer 31 formed thereon to form a photoresist layer 51. After that, exposure and development are carried out to selectively form the photoresist layer 51 on the multiple first electrodes 21. Here, if the first organic compound layer 31 is affected by a solvent included in the photoresist material or by a developer of the photoresist layer, for example, if the first organic compound layer 31 is dissolved in the solvent or the developer, the photoresist layer cannot be formed directly on the first organic compound layer, and thus, it is necessary to form a layer for protecting the first organic compound layer against the solvent or the like. A case where the photoresist layer cannot be formed directly on the organic compound layer is to be described later, and first, a case where the photoresist layer may be formed directly on the organic compound layer is described.

(When Photoresist Layer May Be Formed Directly On Organic Compound Layer)

FIGS. 2A to 2N illustrate a manufacturing method when the photoresist layer may be formed directly on the organic compound layer. FIG. 2A illustrates the above-mentioned step of forming the first organic compound layer 31 on the first electrodes 21 to 23. The photoresist layer 51 is formed on the first organic compound layer 31 (FIG. 2B). The photoresist material may be selected from publicly known photosensitive materials, and the photoresist material may be applied by a publicly known method such as spin coating, dipping, or spray coating. Ultraviolet light 60 or the like is applied to the substrate 10 having the photoresist layer formed thereon via a photomask 61 in a desired pattern using an exposure apparatus (FIG. 2C). After that, the substrate is immersed in a developer, and patterning is carried out so that the photoresist layer is left on the first organic compound layer which is formed on the first electrode 21 (FIG. 2D).

With use of the photoresist layer 51 which is left as the mask, the first organic compound layer 31 is patterned by dry etching (FIG. 2E). The dry etching may be carried out through removal by chemical reaction with an oxygen gas or a fluorine-based gas, through physical removal using an argon gas, or the like depending on the material formed on the substrate. With this dry etching step, the first organic compound layer 31 in a region in which the photoresist layer 51 is not left is removed to expose the surfaces of the first electrodes 22 and 23. Dry etching may remove a film substantially vertically with respect to the substrate, and thus the inclination angles at the edges of the patterned first organic compound layer may be caused to be almost 90°. As a result, patterning which is more precise than that in a case using other methods may be achieved.

Further, the photoresist layer 51 which is left as the mask is dry etched together with the first organic compound when the first organic compound layer is dry etched. Therefore, in order to protect the organic compound layer 31 on the first electrode 21, the photoresist layer may be formed so as to have a sufficient thickness. It is preferred that the thickness of the photoresist layer after the application be about 2 to 5 μm.

Next, the second organic compound layer 32 is formed on the entire substrate 10 having the photoresist layer 51 being left thereon (FIG. 2F). When the second organic compound layer 32 is formed by an applying method, it is necessary that both of the following two requirements be satisfied: a solvent of the second organic compound layer material does not affect the first organic compound layer 31 and the photoresist layer 51; and the solubility of the second organic compound layer 32 in a removing liquid for the photoresist layer 51 is low. However, when the second organic compound layer 32 is formed by vacuum deposition, the requirement that a solvent of the second organic compound layer material does not affect the first organic compound layer 31 and the photoresist layer 51 may be neglected, and a wider range of choice of the material is offered accordingly, which is preferred. The same can be said with regard to the third organic compound layer 33.

The substrate 10 having the second organic compound layer 32 formed thereon is immersed in the removing liquid for dissolving the photoresist layer 51 to, together with the removal of the photoresist layer 51, release the second organic compound layer 32 formed on the photoresist layer 51 (FIG. 2G). Here, the photoresist layer 51 also serves as a release layer for releasing the second organic compound layer 32, but a layer on the surface of the photoresist layer 51 at a thickness of several tens to several hundreds of nanometers is less liable to be dissolved by dry etching. In order to cause the photoresist layer 51 to also serve as a release layer, it is better that, under the layer of the photoresist layer 51 which is less liable to be dissolved after the dry etching, a layer which is liable to be dissolved exists at a sufficiently large thickness, and it is preferred that the thickness of the layer after the dry etching be 1 μm or more. Further, the solubilities of the first organic compound layer and the second organic compound layer in the removing liquid for the photoresist layer 51 are required to be 1/10 or lower, more preferably 1/50 or lower of the solubility of the photoresist layer 51 in the removing liquid. In order to promote the dissolution, the temperature of the removing liquid may be raised to cause the solubility to be higher, or ultrasonic vibrations may be applied to promote the removing liquid to enter the photoresist layer 51. In this way, the organic compound layer 32 which is released together with the layer of the photoresist layer 51 which is less liable to be dissolved is in intimate contact with the surface of the photoresist layer 51 even after the release, and thus becomes large film flakes without being broken into small pieces.

Further, almost none of the film flakes formed of the layer of the released photoresist layer 51 which is less liable to be dissolved and the second organic compound layer 32 are not dissolved in the removing liquid, and thus drift in the removing liquid. In order to prevent the film flakes of the second organic compound layer from adhering to the surface of the patterned substrate 10, it is preferred that the removing liquid be circulated or ultrasonic vibrations be applied thereto. With regard to the substrate 10 after the photoresist layer 51 and the second organic compound layer 32 on the photoresist layer 51 are released therefrom, for the purpose of removing the adhering matter on the surface thereof, it is preferred that the substrate 10 be cleaned with a pure water shower or the like.

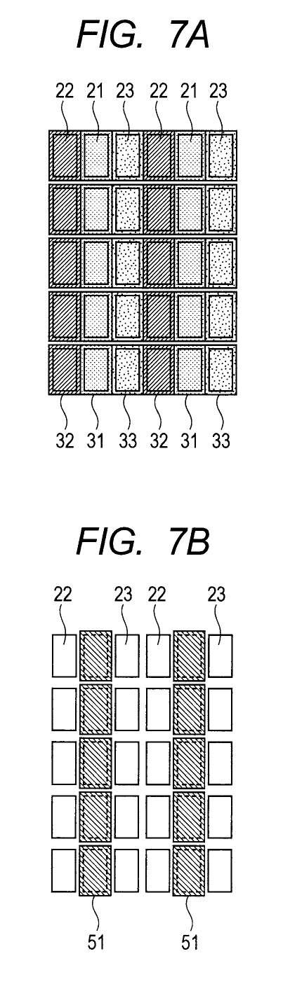

Here, depending on the pattern of the photoresist layer, the adhering matter on the substrate 10 may be reduced. For example, as illustrated in FIGS. 7A and 7B, when the photoresist layer for patterning the first organic compound layer 31 is patterns which are separately formed with respect to the respective first electrodes 21, the size and the number of the film flakes of the second organic compound layer 32 which are to be released depend on the area and the number of the first electrodes 21. For example, when a three-inch full-color display apparatus having a resolution of VGA (640×480 pixels) is manufactured as the organic light emitting device, the first electrodes 21 to 23 are sized to be about 30 μm×100 μm, and the number of each of the first electrodes 21 to 23 is 640×480=307,200. Therefore, the number of the film flakes sized to be 30 μm×100 μm of the second organic compound layer 32 produced at the releasing step is as much as 307, 200, and thus, the possibility that the film flakes adhere to the surface of the substrate 10 to cause defective patterning is very strong.

Therefore, according to the present invention, through formation of the formation pattern of the photoresist layer 51, that is, the first organic compound layer 31, continuously over multiple light emitting portions, each film flake of the second organic compound layer which is released is caused to be large and the number of the film flakes which are produced is reduced. If the number itself of the film flakes of the second organic compound layer which are released is reduced, the possibility that the film flakes adhere to the surface of the substrate 10 may also be reduced. Further, even if the film flakes adhere to the surface of the substrate when released, in a subsequent cleaning step of cleaning with a shower or the like, as the size of one film flake of the second organic compound layer is enlarged, removing force applied by a cleaning liquid increases accordingly, and the possibility that the film flakes are removed becomes stronger.

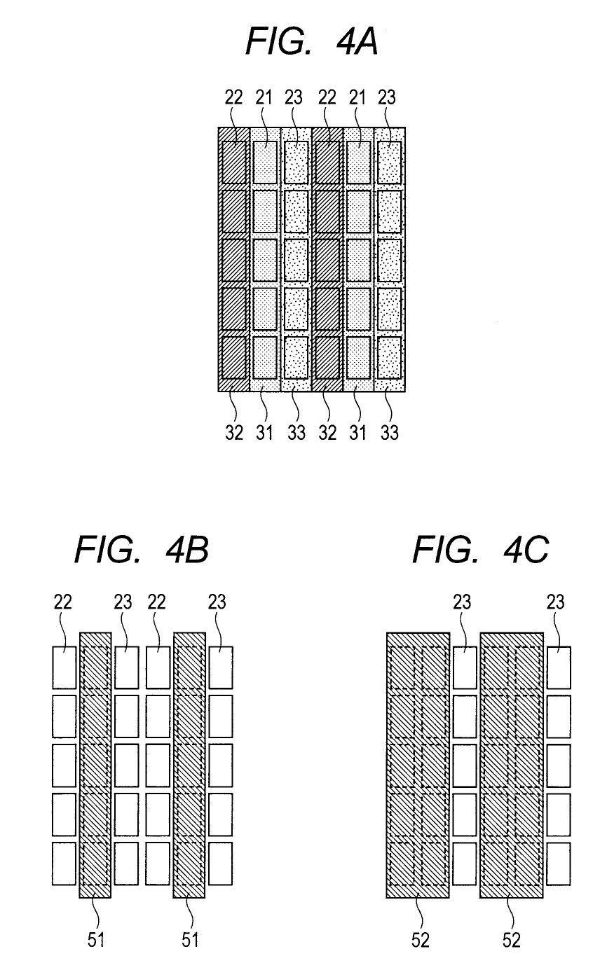

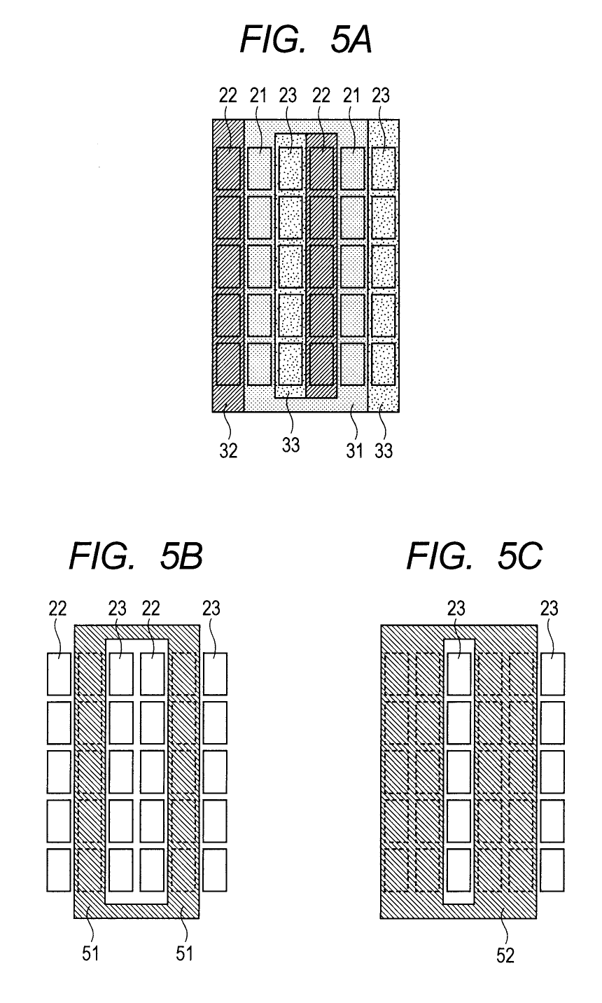

FIGS. 4A to 4C and FIGS. 5A to 5C partially illustrate specific exemplary formation patterns of the organic compound layers according to the present invention. FIG. 4A illustrates a pattern in which the organic compound layers are continuous for one line of the first electrodes. FIG. 5A illustrates a pattern in which the first organic compound layer 31 is continuous for two lines of the first electrodes 21. Each of FIG. 4B and FIG. 5B illustrates a pattern of the photoresist layer which is formed when the first organic compound layer is patterned. The second organic compound layer 32 having the size corresponding to the pattern is to be released together with the photoresist layer. The manufacturing method according to the present invention is not limited to these specific examples, and various kinds of patterns may be used insofar as the organic compound layers are formed continuously over multiple light emitting portions.

After the photoresist layer 51 and the second organic compound layer 32 on the photoresist layer 51 are removed, a photoresist layer 52 is newly formed on the entire surface of the substrate 10 having the first and second organic compound layers provided thereon (FIG. 2H). The formation pattern of the photoresist layer 52 may determine the formation pattern of the second organic compound layer 32. The new photoresist layer 52 may be formed similarly to the case of the photoresist layer 51 formed earlier. Then, the newly formed photoresist layer 52 is patterned using a photomask 62 so as to be left on the first organic compound layer 31 and on the second organic compound layer 32 which is formed on the first electrode 22 (FIGS. 2I and 2J). Similarly to the patterning of the first organic compound layer 31, the second organic compound layer is also patterned so as to be continuous over multiple first electrodes 22. With regard to the examples illustrated in FIGS. 4A to 4C and FIGS. 5A to 5C, respectively, FIG. 4C and FIG. 5C illustrate formation patterns of the photoresist layer when the second organic compound layer 32 is patterned. With regard to the photoresist layer 52 for patterning the second organic compound layer 32, the size is larger than that of the photoresist layer 51 for patterning the first organic compound layer 31 and the number is smaller than that of the photoresist 51, and thus, the released film flakes are less liable to adhere to the substrate 10.

With use of the photoresist layer 52 left on the substrate 10 as the mask, similarly to the case of the first organic compound layer 31, a part of the second organic compound layer 32 on which the photoresist layer 52 is not left is dry etched to expose the surface of the first electrode 23 (FIG. 2K). Next, the third organic compound layer 33 is formed on the substrate 10 having the photoresist layer 52 left thereon over the entire surface or in a predetermined region including the light emitting region 12 using a vapor deposition mask or the like (FIG. 2L). After that, the photoresist layer 51 is brought into contact with a removing liquid to release the third organic compound layer 33 formed on the photoresist layer 52 (FIG. 2M).

Note that, when the third organic compound layer 33 is formed without using a vapor deposition mask or the like, it is good to form the photoresist layer 52 which is formed in advance when the second organic compound layer 32 is patterned also on the external connection terminal 15 and the contact portion 11. Then, when the third organic compound layer 33 is released, the surfaces of the external connection terminal 15 and the contact portion 11 may be exposed at the same time.

Finally, the second electrode 70 and the encapsulation layer (not shown) are formed on the first to third organic compound layers, and then, the organic light emitting device is completed in which the first organic compound layer 31 is formed in the first light emitting portion, the second organic compound layer 32 is formed in the second light emitting portion, and the third organic compound layer 33 is formed in the third light emitting portion (FIG. 2N).

(When Photoresist Layer Cannot Be Formed Directly On Organic Compound Layer)

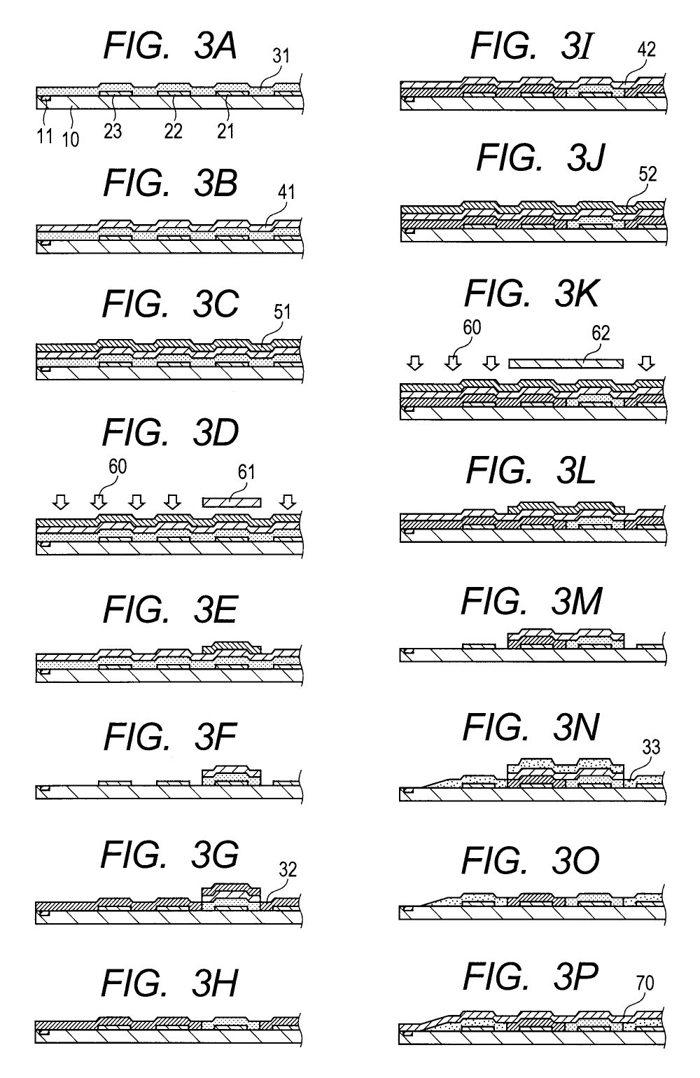

Next, a manufacturing method is described when the photoresist layer cannot be formed directly on the organic compound layer, that is, when the organic compound layers are dissolved in a solvent of the photoresist material, a developer or a removing liquid of the photoresist layer, or the like. FIGS. 3A to 3P illustrate a method of manufacturing an organic emission layer when the photoresist layer cannot be formed directly on the organic compound layer. Description of points which are the same as those when the photoresist layer may be formed directly on the organic compound layer are omitted and only different points are described in the following.

FIG. 3B illustrates a step of, after forming the first organic compound layer on the substrate 10 having the multiple first electrodes 21 to 23 formed thereon (FIG. 3A) and before the photoresist layer 51 is formed, forming a protective layer 41 for protecting the first organic compound layer. Through provision of the protective layer 41, the photoresist layer 51 may be formed without dissolving the first organic compound layer 31.

The protective layer 41 at least includes the release layer. The words “release layer” as used herein mean a layer with a high degree of solubility in a solution in which almost none of the organic compound layer is dissolved. The solubility of the organic compound layer in the removing liquid for the release layer is 1/10 or lower, more preferably 1/50 or lower of the solubility of the release layer. As a release layer which satisfies such a requirement, a material which is soluble in water such as a water-soluble high-molecular material or a water-soluble inorganic salt may be suitably used. Therefore, the release layer may remove the photoresist layer and the second organic compound layer 32 formed on the photoresist layer without dissolving the first organic compound layer 31 and the second organic compound layer 32. Exemplary water-soluble high-molecular materials include polyvinyl alcohol (PVA), a polyacrylic acid-based polymer, polyethylene glycol (PEG), polyethylene oxide (PEO), and polyvinyl pyrrolidone (PVP).

If the release layer does not allow the solvent of the photoresist material, the developer of the photoresist layer, or the like to pass therethrough to the organic compound layer and the release layer is not dissolved in such a liquid, it is sufficient that only the release layer is formed on the organic compound layer as the protective layer. However, if the release layer allows the solvent of the photoresist material, the developer of the photoresist layer, or the like to pass therethrough or is dissolved in such a liquid, the release layer is a first protective layer and a second protective layer is further formed between the release layer and the photoresist layer 51. Provision of the second protective layer enables formation of the photoresist layer 51 without dissolving the first organic compound layer 31. As the second protective layer, an inorganic film highly resistant to moisture of silicon nitride, silicon oxide, aluminum oxide, or the like is suitable. With regard to the method of forming the protective layer 41, for example, a release layer formed of a water-soluble high-molecular material (first protective layer) may be formed using publicly known methods including an applying method such as spin coating or dip coating. The second protective layer may be formed by a known method such as a sputtering method and a CVD method. After the protective layer 41 is formed, the photoresist layer 51 is formed similarly to the case where the protective layer 41 is not formed (FIGS. 3C to 3E).

Then, the first organic compound layer 31 is patterned by dry etching with use of the photoresist layer 51 as the mask (FIG. 3F). When the first organic compound layer 31 is dry etched, it is necessary to also remove the protective layer 41 in a region in which the photoresist layer is not left. The method used for the dry etching and the etching gas used may be appropriately selected according to the materials of the protective layer 41 and of the first organic compound layer 31. For example, a second protective layer formed of an inorganic material is suitably etched using a chemically reactive gas such as CF₄, while a release layer formed using a water-soluble high-molecular material (first protective layer) is suitably etched using oxygen gas. FIG. 3F illustrates a state in which the photoresist layer 51 is removed while the first organic compound layer 31 is dry etched. Even if the photoresist layer 51 is removed as illustrated in FIG. 3F, no problem arises insofar as the protective layer 41 is left at the time when the patterning of the first organic compound layer 31 is completed. After the photoresist layer 51 is removed, the protective layer 41 acts as the etching mask. Of course, no problem arises even if the photoresist layer 51 is left at the time when the patterning of the first organic compound layer 31 is completed.

The second organic compound layer 32 is formed on the entire surface of the substrate 10 having the protective layer 41 left on the surface of the patterned first organic compound layer 31 formed thereon (FIG. 3G). After that, the substrate 10 having the second organic compound layer 32 formed thereon is immersed in the removing liquid for the release layer (first protective layer). Then, together with the dissolution of the release layer, the second organic compound layer 32 formed on the release layer is released. In the case where the second protective layer is formed, the dissolution of the release layer also allows the second organic compound layer to be released. When the release layer is formed of a water-soluble high-molecular material, as the removing liquid, pure water or a mixed liquid prepared by mixing pure water with a 10 to 50% organic solvent such as isopropyl alcohol may be used. Through mixing of pure water with a proper amount of an organic solvent, the solubility of the second organic compound layer 32 may be kept low, and at the same time, the solubility of the release layer may be enhanced. From the same reason, it is also preferred to heat the removing liquid when used.

If an edge of the release layer is covered with the second organic compound layer 32, the removing liquid is less liable to pass therethrough. Therefore, it is preferred that the following first to third techniques be used solely or in combination as necessary. The first technique is to form the organic compound layers in decreasing order of thickness. The second technique is to cause the thickness of the release layer to be larger than the sum of the thickness of the first organic compound layer and the thickness of the second organic compound layer. The third technique is to cause the layer left on the surface of the first organic compound layer 31 after the first organic compound layer 31 is patterned to be a hundred times as thick as the second organic compound layer 32 or thicker to suppress formation of the second organic compound layer 32 at the edges. Through use of those techniques, the removing liquid is allowed to enter from the edges of the release layer to carry out the release with efficiency.

After the second organic compound layer 32 formed on the protective layer 41 is removed together with the protective layer 41 (FIG. 3H), a protective layer 42 and the photoresist layer 52 are newly formed in a predetermined pattern, and the second organic compound layer 32 is patterned by dry etching with use of the protective layer 42 and the photoresist layer 52 as the mask (FIGS. 3I to 3M). After the dry etching, the third organic compound layer 33 is formed on the substrate 10 with at least the protective layer 42 being left on the first electrodes 21 and 22 (FIG. 3N), and the third organic compound layer 33 on the photoresist layer 52 is released together with the protective layer 42 (FIG. 3O). Those steps may be carried out similarly to the steps described above.

When a water-soluble material is used as the release layer, it is not appropriate to use a water-soluble material as a layer which is formed prior to the emission layers. However, no problem arises insofar as such a layer of a water-soluble material is formed after the first to third emission layers are patterned. For example, a material including an alkali metal or an alkaline-earth metal with high electron injection ability is a material preferred as the electron injection layer, but the electron injection ability is lost by reaction with moisture or oxygen, and thus, it is difficult for the material to go without a problem through a step of being brought into contact with pure water or a mixed liquid prepared by mixing pure water with an organic solvent. Therefore, when a material including an alkali metal or an alkaline-earth metal is used as the electron injection layer, after the step of patterning the third organic compound layer 33 (FIG. 3O) is completed, the material is used to form an electron injection layer which is common to the first to third light emitting portions. After the electron injection layer is formed, the second electrode 70 is formed (FIG. 3P) and the encapsulation layer is provided.

As described above, through formation of the release layer continuously over multiple light emitting portions, when the release layer is brought into contact with the removing liquid to be selectively dissolved, the size of the released film flakes of the second organic compound layer and the like may be caused to be large. Therefore, compared with a case where the organic compound layers are separately patterned with respect to the respective first electrodes, the number of the released film flakes may be reduced, and adhesion of the released film flakes to the substrate may be suppressed. As a result, leakage, a short circuit, light emission failure, and the like which are caused by adhesion of the released film flakes to the substrate after the patterning may be suppressed and an organic light emitting device having satisfactory performance may be obtained.

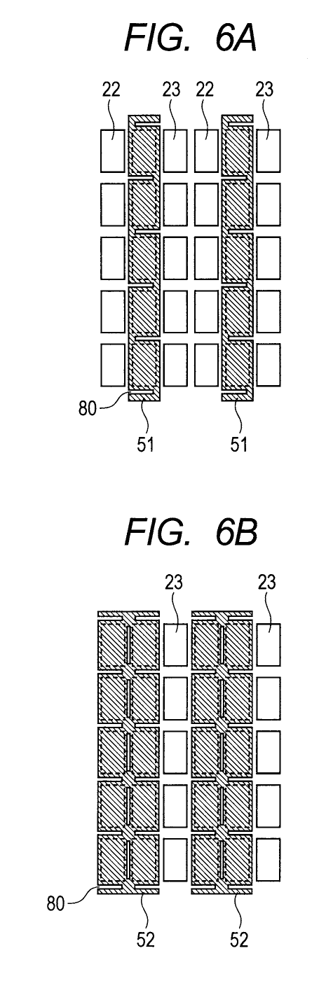

By the way, when the release layer is brought into contact with the removing liquid to be dissolved therein, the removing liquid gradually enters from the edges of the release layer. Therefore, it takes a long time for the removing liquid to enter the release layer having a relatively large area as in the present invention from the edges thereof and to dissolve the entire release layer, which causes a problem that the productivity is lowered. Therefore, according to the present invention, in order to improve the productivity, it is good to, when the photoresist layers for patterning the respective organic compound layers are formed, provide a slit for allowing the removing liquid to pass through a region which does not emit light (non-light emitting portion). FIGS. 6A and 6B illustrate exemplary patterns which are an improvement of the patterns illustrated in FIGS. 4A to 4C and which may shorten the time necessary for the release. FIG. 6A illustrates a pattern of the photoresist layer when the first organic compound layer 31 is patterned, and FIG. 6B illustrates a pattern of the photoresist layer when the second organic compound layer 32 is patterned. In both of the patterns of the photoresist layers, slits 80 for allowing the removing liquid to enter the non-light emitting portion are arranged so as to be away from over the first electrodes which are the light emitting portions. In FIGS. 6A and 6B, the slits 80 are provided away from over the first electrodes which are the light emitting portions, but the locations at which the slits 80 are provided are not specifically limited insofar as the locations are in non-light emitting portions. For example, when a first electrode is divided by a partition layer, the slits 80 may be provided on the partition layer. The slits 80 may be appropriately designed depending on the areas and the arrangement of the light emitting portions, but it is preferred that the patterns of the photoresist layers be not disconnected midway through the process. Through provision of the slits 80 in this way, even if the release layer is formed in a large pattern which is continuous over multiple light emitting portions, the number of paths through which the removing liquid enters increases and thus, the removing liquid may pass through the release layer in a short time to improve the productivity. The slits are not limited to the exemplary slits illustrated in FIGS. 6A and 6B, and may be arbitrarily provided insofar as the slits are provided in a non-light emitting portion and the release layers are formed continuously over multiple light emitting portions.

Further, the pattern according to the present invention is not limited to the stripe-like one illustrated in FIGS. 4A to 4C and FIGS. 5A to 5C, and may be a delta-like one. In this case, also, a slit may be similarly provided as necessary.

Examples of the present invention are specifically described in the following.

### EXAMPLE 1

An example in which the organic light emitting device was manufactured by the manufacturing method illustrated in FIGS. 2A to 2N is described. In this example, the organic compound layers were formed in the patterns illustrated in FIGS. 4A to 4C.

As the substrate 10, a glass substrate having a circuit layer which included a transistor and an insulating layer which covered the circuit layer provided thereon was prepared. After Ag and IZO were deposited in sequence on an entire surface of the substrate 10 by sputtering, patterning for dividing the substrate 10 into the respective light emitting portions was carried out to form the multiple first electrodes 21 to 23 in the row direction and in the column direction.

After UV ozone treatment was carried out to clean the surfaces of the first electrodes, poly(3,4-ethylenedioxythiophene)/polystyrene sulfonate (PEDT/PSS: Baytron P manufactured by Bayer) was applied by spin coating to the entire surface of the substrate having the first electrodes formed thereon and dried to form the hole injection layer having a thickness of 1,000 Å. Then, a solution of 2 wt % toluene a main component of which is polyvinyl carbazole was applied by spin coating to the entire surface of the hole injection layer and dried to form the first emission layer having a thickness of 800 Å. As described above, in this example, the first organic compound layer 31 including the hole injection layer and the first emission layer was formed (FIG. 2A).

A positive photoresist material (OFPR-800 manufactured by TOKYO OHKA KOGYO CO., LTD.) was dropped onto the first organic compound layer 31 and a film having a thickness of 1 μm was formed by spin coating. Then, prebake at 80° C. for 30 minutes was carried out (FIG. 2B). The substrate 10 having the photoresist layer 51 formed thereon was set in an exposure apparatus and exposure was carried out so that the photoresist layer was left on the multiple first electrodes 21 on which the first light emitting portions were to be provided (FIG. 2C). In the exposure, the photomask 61 having a light shielding pattern which was the same as that of the photoresist layer 51 illustrated in FIG. 4B formed thereon was used. The light shielding pattern was continuous over one line of the multiple first electrodes 21.

Next, the substrate 10 after the exposure was immersed in a developer (NMD-3 manufactured by TOKYO OHKA KOGYO CO., LTD.) to carry out development. After that, the substrate 10 was rinsed under running water and then baked. The substrate 10 with a portion of the photoresist layer which was not exposed by the development being removed was introduced into a dry etching apparatus. With use of the photoresist layer which was left as the mask, the first organic compound layer was etched by oxygen plasma to be removed (FIG. 2E).

Similarly to the case of the first organic compound layer 31, the second organic compound layer 32 including the hole injection layer and the second emission layer was formed on the entire surface of the substrate 10 having the first organic compound layer 31 and the photoresist layer 51 left thereon (FIG. 2F). The same material as that of the first organic compound layer was used to form the hole injection layer at a thickness of 600 Å. The second emission layer was formed at a thickness of 500 Å by applying by spin coating a solution of 1 wt % xylene, a main component of which was a polyparaphenylene vinylene derivative high-molecular material (MEH-PPV), to the entire upper surface of the hole injection layer and drying the solvent. The substrate 10 having the second organic compound layer 32 formed thereon was immersed in acetone and ultrasonic vibrations were applied thereto to dissolve the photoresist layer 51, thereby releasing the photoresist layer 51 together with the second organic compound layer 32 formed on the photoresist layer 51 (FIG. 2G).

Next, similarly to the above-mentioned step, a new photoresist layer was formed on the substrate 10 having the first organic compound layer 31 and the second organic compound layer 32 formed thereon (FIG. 2H). In the exposure, the photomask 62 having a light shielding pattern which was the same as that of the photoresist layer 52 illustrated in FIG. 4C was used (FIG. 2I). The light shielding pattern was continuous over two lines of the first electrodes 21 and the first electrodes 22 which were adjacent to each other. The substrate 10 after the exposure was immersed in the developer (NMD-3 manufactured by TOKYO OHKA KOGYO CO., LTD.) to carry out development. After the substrate 10 was rinsed under running water, the substrate 10 was introduced into a dry etching apparatus, and a portion of the second organic compound layer with the photoresist layer 52 thereon being removed was etched by oxygen plasma to be removed (FIG. 2J).

Similarly to the cases of the first and second organic compound layers, as the third organic compound layer 33, the hole injection layer at a thickness of 400 Å and the third emission layer were formed on the substrate having the photoresist layer left thereon (FIG. 2L). The third emission layer was formed at a thickness of 400 Å by applying by spin coating a solution of 1 wt % xylene, a main component of which was a polyparaphenylene vinylene derivative high-molecular material (MEH-PPV), to the entire surface and carrying out drying.

Next, similarly to the case of the photoresist layer 51, the photoresist layer 52 was dissolved to be removed together with the third organic compound layer 33 formed thereon (FIG. 2M). On the substrate 10, the surfaces of the first organic compound layer 31, the second organic compound layer 32, and the third organic compound layer 33 which were formed in the pattern illustrated in FIG. 4A were exposed. The substrate 10 with the patterning of the respective emission layers thereon being completed was heated at 100° C. for 30 minutes. After the heat was dissipated sufficiently, Ag and Mg were co-evaporated and the second electrode 70 in which the ratio of Ag to Mg was about 8:2 was formed at a thickness of 20 nm (FIG. 2N). Finally, the substrate 10 having the second electrode 70 formed thereon was transferred to a glove box coupled to a vacuum evaporator, and encapsulation in a cap glass with a desiccant being placed therein was carried out in a nitrogen atmosphere.

Current was passed through multiple organic light emitting device manufactured by the above-mentioned method, and light emission by the respective light emitting portions was confirmed. No conspicuously defective light emission was observed throughout the light emitting portions, and satisfactory light emission could be obtained in all the light emitting portions.

### EXAMPLE 2

This example differs from Example 1 in that the respective organic compound layers were formed by vacuum deposition, that functional layers other than the electron injection layer were formed, that a protective layer was provided between the respective organic compound layers and the photoresist layers, and that silicon nitride was used to form the encapsulation layer. The manufacturing steps of this example were similar to those illustrated in FIGS. 3A to 3P. In this example, the respective organic compound layers were formed in the patterns illustrated in FIGS. 5A to 5C.

Similarly to the case of Example 1, a glass substrate having a circuit layer formed thereon was used as the substrate 10 and the multiple first electrodes 21 to 23 were formed. After that, the surfaces of the first electrodes were cleaned similarly to the case of Example 1, and then, as the first organic compound layer, a laminated film including the hole transport layer, the first emission layer, and the electron transport layer was formed (FIG. 3A). As the hole transport layer, a film of α-NPD at a thickness of 2,000 Å was formed. As the first emission layer (red emission layer), a film of CBP doped with Ir(piq)3 at a thickness of 300 Å was formed. As the hole blocking layer, a film of a chrysene-based material at a thickness of 100 Å was formed. All of these layers were formed by vacuum deposition in the stated order.

Next, as the release layer (first protective layer), polyvinyl pyrrolidone (PVP) was dissolved in pure water to prepare a 5 wt % solution, which was applied by spin coating to the entire surface having the first organic compound layer formed thereon. Then, heating was carried out at 100° C. for 10 minutes to form the release layer at a thickness of 0.5 μm. After the release layer was formed, the substrate 10 was introduced into a CVD film formation apparatus. As the second protective layer, a silicon nitride film was formed at a thickness of 3 μm to be the protective layer 41 (FIG. 3B).

A photoresist layer patterned in a way similar to that in the case of Example 1 was formed on the silicon nitride film (FIGS. 3C to 3E). The substrate 10 having the photoresist layer left at the location of the first light emitting portion was introduced into a dry etching apparatus, and the silicon nitride film as the second protective layer was etched to be removed by CF₄ plasma. Next, oxygen plasma was used to continuously remove the PVP and the first organic compound layer (FIG. 3F). Here, oxygen plasma also etched the surface of the photoresist. At the time when the removal of the PVP and the first organic compound layer was completed, the photoresist layer was removed and the surface of the second protective layer was exposed.

The substrate 10 having the protective layer left at the location of the first light emitting portion was introduced into a vacuum film formation apparatus, and the second organic compound layer 32 was formed by vacuum deposition (FIG. 3G). In forming the second organic compound layer 32, a hole injection layer of molybdenum oxide at a thickness of 10 Å, a hole transport layer of α-NPD at a thickness of 1,600 Å, a second emission layer (green emission layer) formed by doping Alq3 with coumarin 6 at a thickness of 300 Å, and a hole blocking layer of a chrysene-based material at a thickness of 100 Å were laminated in the stated order.

The substrate 10 having the second organic compound layer 32 formed thereon was immersed in pure water and ultrasonic vibrations were applied thereto to dissolve the PVP, thereby releasing the silicon nitride film and the second organic compound layer formed on the silicon nitride film together with the PVP (FIG. 3H). Then, similarly to the above-mentioned method, after the PVP and the silicon nitride film were formed on the first organic compound layer 31 and the second organic compound layer 32, the PVP, the silicon nitride film, and the second organic compound layer on the first electrode 23 were removed (FIGS. 3I to 3M).

The third organic compound layer 33 was formed using a vacuum film formation apparatus on the substrate 10 having the protective layer left on the first electrodes 21 and 22 (FIG. 3N). In forming the third organic compound layer, a hole injection layer of molybdenum oxide at a thickness of 10 Å, a hole transport layer of α-NPD at a thickness of 1,000 Å, a third emission layer (blue emission layer) formed by doping an anthracene derivative with perylene at a thickness of 300 Å, and a hole blocking layer of a chrysene-based material at a thickness of 100 Å were laminated in the stated order.

Similarly to the above-mentioned step, the substrate 10 was immersed in pure water and ultrasonic vibrations were applied thereto to dissolve the PVP, thereby releasing the silicon nitride film and the third organic compound layer formed on the silicon nitride film together with the PVP (FIG. 3O). On the substrate 10, the surfaces of the first organic compound layer 31, the second organic compound layer 32, and the third organic compound layer 33 which were formed in the pattern illustrated in FIG. 4A were exposed.

The substrate 10 was introduced into a vacuum atmosphere and heated at 100° C. for 30 minutes, and the heat was dissipated sufficiently. After that, the electron transport layer and the electron injection layer which were common to the first to third light emitting portions were formed by vacuum film formation (not shown). As the electron transport layer, a film of bathophenanthroline was formed at a thickness of 100 Å. As the electron injection layer, bathophenanthroline and cesium carbonate (Cs₂CO₃) were co-evaporated so that the volume ratio thereof was 7:3 and so that the thickness was 60 nm. After that, the second electrode 70 of Ag was formed by sputtering at a thickness of 12 nm (FIG. 3P). Finally, as the encapsulation layer, a silicon nitride film was formed by CVD at a thickness of 6 μm on the entire surface of the substrate 10 having the light emitting portions formed thereon.

Current was passed through multiple organic light emitting device obtained by the above-mentioned method, and light emission by the respective light emitting portions was confirmed. No conspicuously defective light emission was observed throughout the light emitting portions, and satisfactory light emission could be obtained in all the light emitting portions.

### EXAMPLE 3

This example differs from Example 1 in that the respective organic compound layers were formed in the patterns illustrated in FIGS. 6A and 6B. The manufacturing steps were the same as those of Example 1, and thus, description thereof is omitted here.

In this example, as illustrated in FIGS. 6A and 6B, slits were formed in a non-light emitting portion to increase the number of paths through which the removing liquid entered, and thus, the second organic compound layer 32 and the third organic compound layer 33 could be released by dissolving the release layer in a shorter time than in the case of Example 1. Current was passed through multiple organic light emitting device obtained, and light emission by the respective light emitting portions was confirmed. No conspicuously defective light emission could be observed throughout the light emitting portions, and satisfactory light emission could be obtained in all the light emitting portions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2011-074837, filed Mar. 30, 2011, and No. 2011-191414, filed Sep. 2, 2011 which are hereby incorporated by reference herein in their entirety.

### REFERENCE SIGNS LIST

10 substrate
11 contact portion
12 light emitting region
15 external connection terminal
21 to 23 first electrode
31 first organic compound layer
32 second organic compound layer
33 third organic compound layer
41 protective layer
51 to 52 photoresist layer
70 second electrode

What is claimed is:

1. A method of manufacturing an organic light emitting device, comprising:
forming a first organic compound layer on a substrate having multiple first electrodes formed thereon corresponding to multiple light emitting portions, the first organic compound layer at least including a first emission layer;
selectively forming on the first organic compound layer a release layer continuously over a part of the multiple first electrodes;
removing a part of the first organic compound layer on which the release layer is not formed;
forming a second organic compound layer on a part of the substrate from which the first organic compound layer is removed and on the release layer, the second organic compound layer at least including a second emission layer; and
bringing the release layer into contact with a removing liquid for selectively dissolving the release layer and removing the release layer and the second organic compound layer formed on the release layer.

2. The method of manufacturing an organic light emitting device according to claim 1, further comprising, after the removing the release layer and the second organic compound layer formed on the release layer,
selectively forming another release layer continuously on the first organic compound layer and over a part of the multiple first electrodes on which the first organic compound layer is not formed;
removing a part of the second organic compound layer on which the another release layer is not formed;
forming a third organic compound layer on the another release layer and on a part of the multiple first electrodes on which the another release layer is not formed, the third organic compound layer at least including a third emission layer; and
bringing the another release layer into contact with a removing liquid for selectively dissolving the another release layer and removing the another release layer and the third organic compound layer formed on the another release layer.

3. The method of manufacturing an organic light emitting device according to claim 1, wherein the selectively forming on the first organic compound layer a release layer continuously over a part of the multiple first electrodes comprises providing a slit in the release layer in a non-light emitting portion.

4. The method of manufacturing an organic light emitting device according to claim 2, wherein the selectively forming another release layer continuously on the first organic compound layer and over a part of the multiple first electrodes on which the first organic compound layer is not formed comprises providing a slit in the release layer in a non-light emitting portion.
